(19) United States
(12) Patent Application Publication
(10) Pub. No.: US 2025/0318268 A1
(43) Pub. Date: Oct. 9, 2025

(54) DISPLAY DEVICE AND MANUFACTURING METHOD THEREFOR

(71) Applicant: TOVIS CO., LTD., Incheon (KR)

(72) Inventor: Yong Beom KIM, Incheon (KR)

(21) Appl. No.: 18/863,351

(22) PCT Filed: May 9, 2023
(86) PCT No.: PCT/KR2023/006274

§ 371 Date: Nov. 6, 2024

(30) Foreign Application Priority Data
May 12, 2022 (KR) 10-2022-0058269

(51) Int. Cl. H10D 86/60; H10D 86/40

(52) U.S. Cl. CPC H10D 86/60; H10D 86/441

(57) ABSTRACT

A display device according to an embodiment includes: a color filter substrate; a transistor substrate including an overlapping portion facing the color filter substrate and overlapping the color filter substrate, and a protruding portion protruding further outward than the color filter substrate; a driving connection film attached on the protruding portion of the transistor substrate; and a glass adhesive disposed on a lower side of the protruding portion of the transistor substrate, wherein the transistor substrate includes a first slimming portion, and a first non-slimming portion that is disposed around the first slimming portion in plan view and has a thickness greater than the thickness of the first slimming portion, the color filter substrate includes a second slimming portion, and a second non-slimming portion that is disposed around the second slimming portion in plan view and has a thickness greater than the thickness of the second slimming portion, the first non-slimming portion includes a (1-1)-th non-slimming portion disposed across the protruding portion and the overlapping portion, the second non-slimming portion includes a (2-1)-th non-slimming portion, an inner side surface of the (1-1)-th non-slimming portion is positioned further outward than an inner side surface of the (2-1)-th non-slimming portion, and the glass adhesive overlaps the (1-1)-th non-slimming portion.

### TECHNICAL FIELD

The present disclosure relates to a display device and a method of fabricating thereof.

### BACKGROUND ART

A display device is an electronic device for displaying images, and recently, as technology thereof has advanced, research is being conducted on a curved display device to increase the immersive experience of images.

The curved display device provides the immersive experience because a surface on which the image is viewed is curved, giving a viewer the feeling as if the viewer is positioned in a space, and the typical curved display device may be fabricated by making a thickness of a flat display device thin and then curving the display panel.

In order to fabricate the curved display device, the curved display device may be fabricated by designing the display device to be thin when first fabricated, but if this is not possible, the curved display device may also be fabricated by performing a process such as etching or polishing (hereinafter referred to as “slimming”) to make the thickness of the produced display device thinner and then curving the produced display device. The etching process for slimming may be performed by disposing masking members to prevent damage to conductive patterns and circuit portions by the etchant and spraying or flowing the etchant onto the members to be etched.

### DISCLOSURE

### Technical Problem

Aspects of the present disclosure provide a display device that reduces damage to a slimming area due to a physical impact.

Aspects of the present disclosure also provide a method of fabricating a display device that reduces damage to a slimming area due to a physical impact.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### Technical Solution

According to an aspect of the present disclosure, there is provided a display device including: a color filter substrate; a transistor substrate including an overlapping portion facing the color filter substrate and overlapping the color filter substrate, and a protruding portion protruding further outward than the color filter substrate; a driving connection film attached on the protruding portion of the transistor substrate; and a glass adhesive disposed on a lower side of the protruding portion of the transistor substrate, wherein the transistor substrate includes a first slimming portion, and a first non-slimming portion that is disposed around the first slimming portion in plan view and has a thickness greater than the thickness of the first slimming portion, the color filter substrate includes a second slimming portion, and a second non-slimming portion that is disposed around the second slimming portion in plan view and has a thickness greater than the thickness of the second slimming portion, the first non-slimming portion includes a (1-1)-th non-slimming portion disposed across the protruding portion and the overlapping portion, the second non-slimming portion includes a (2-1)-th non-slimming portion, an inner side surface of the (1-1)-th non-slimming portion is positioned further outward than an inner side surface of the (2-1)-th non-slimming portion, and the glass adhesive overlaps the (1-1)-th non-slimming portion.

According to another aspect of the present disclosure, there is provided a method of fabricating a display device, the method includes: preparing an upper target substrate and a lower target substrate facing the upper target substrate, the lower target substrate including an overlapping portion overlapping the upper target substrate and a protruding portion protruding further outward than the upper target substrate; disposing a driving connection film having a driving chip mounted thereon on the protruding portion of the lower target substrate; disposing a first resin in direct contact with the driving connection film and in direct contact with an outer side surface of the upper target substrate; disposing a second lower resin on an edge portion of the lower target substrate and disposing a second upper resin on an edge portion of the upper target substrate; masking the edge portion of the lower target substrate, the edge portion of the upper target substrate, and the driving connection film using a masking member; forming a lower substrate including a first slimming portion and a first non-slimming portion around the first slimming portion, and an upper substrate including a second slimming portion and a second non-slimming portion around the second slimming portion, respectively, by slimming the lower target substrate and an exposed portion of the upper target substrate; removing the masking member from the lower substrate and the upper substrate; disposing a polarizing member on each of the first slimming portion and the second slimming portion; bending the lower substrate and the upper substrate; and disposing a glass adhesive on a lower side of the protruding portion of the lower substrate, wherein the first non-slimming portion includes a (1-1)-th non-slimming portion disposed across the protruding portion and the overlapping portion, the second non-slimming portion includes a (2-1)-th non-slimming portion, an inner side surface of the (1-1)-th non-slimming portion is positioned further outward than an inner side surface of the (2-1)-th non-slimming portion, and the glass adhesive overlaps the (1-1)-th non-slimming portion.

Details of other embodiments are included in the detailed description and drawings.

### Advantageous Effects

According to the display device and the method of fabricating the display device according to embodiments, the slimming area may be reduced from being damaged by the physical impact.

However, the effects of the embodiments are not restricted to the one set forth herein. The above and other effects of the exemplary embodiments will become more apparent to one of daily skill in the art to which the embodiments pertain by referencing the claims.

### DESCRIPTION OF DRAWINGS

FIG. 1 is a plan view of a display device according to an exemplary embodiment;

FIG. 2 is a plan view illustrating in detail a first substrate, a driving connection film, and a driving circuit board of the display device according to FIG. 1;

FIG. 3 is a plan view illustrating in detail a second substrate of the display device according to FIG. 1;

FIG. 4 is a plan view illustrating in detail the display device according to FIG. 1;

FIG. 5 is a cross-sectional view taken along line I-I′ of FIG. 4;

FIG. 6 is a cross-sectional view taken along line II-II′ of FIG. 4;

FIG. 7 is a cross-sectional view taken along line III-III′ of FIG. 4;

FIG. 8 is an enlarged cross-sectional view of area A of FIG. 6;

FIGS. 9 and 10 are cross-sectional views illustrating a state in which the display device according to FIG. 1 is folded;

FIGS. 11 to 22 are cross-sectional views for each process of a method of fabricating a display device according to an embodiment;

FIG. 23 is a cross-sectional view of a display device according to another embodiment:

FIG. 24 is a cross-sectional view of a display device according to still another embodiment; and

FIGS. 25 and 26 are cross-sectional views of a display device according to still another embodiment.

### MODE FOR INVENTION

Advantages and features of the present disclosure and methods of achieving the same will become apparent with reference to the embodiments described below in detail in conjunction with the accompanying drawings. However, the present disclosure is not limited to embodiments to be described below, but may be implemented in various different forms, the present embodiments will be provided only in order to make the present disclosure complete and allow one of ordinary skill in the art to which the present disclosure pertains to completely recognize the scope of the present disclosure, and the present disclosure will be defined by the scope of the claims.

When an element or layer is referred to as being “on” another element or layer, it includes both a case in which the element or layer is directly on another element or layer and a case in which the element or layer is on another element or layer with the other element or layer interposed therebetween. The same reference numbers indicate the same components throughout the specification.

It will be understood that, although the terms “first”, “second”, and the like may be used to describe various components, these components should not be limited by these terms. These terms are only used to distinguish one component from another component. Accordingly, a first component discussed below could be termed a second component without departing from the teachings of the present disclosure.

Hereinafter, specific embodiments will be described with reference to the accompanying drawings.

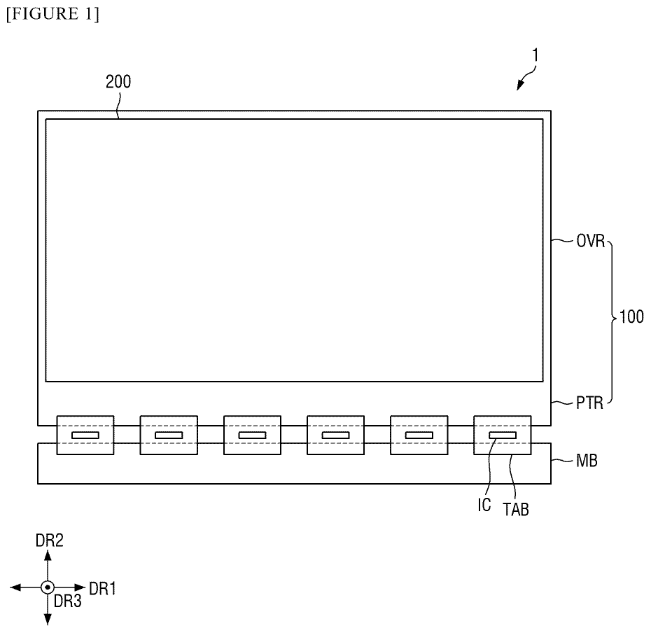

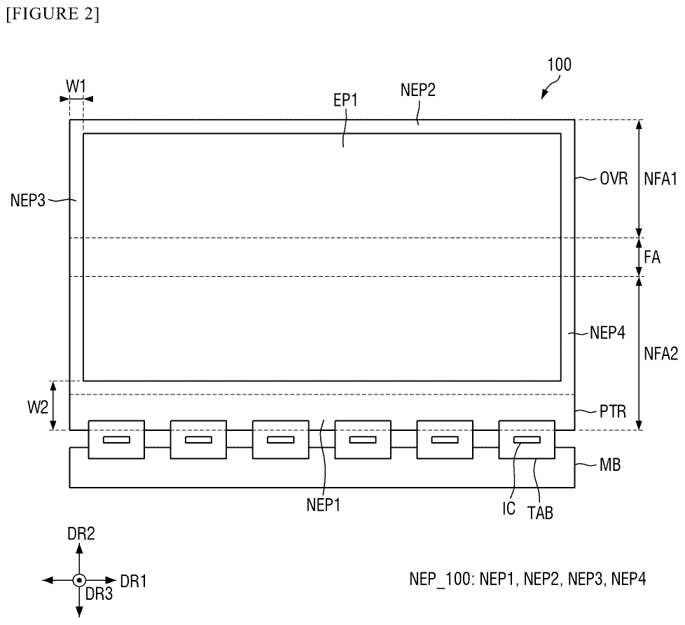

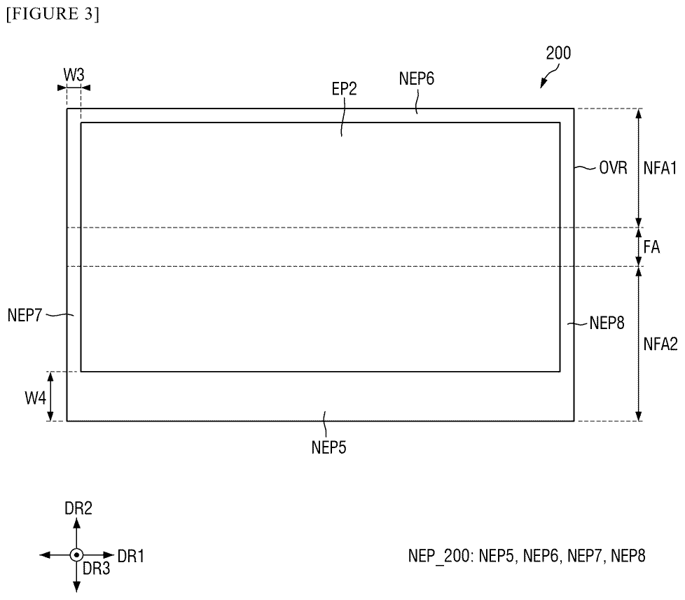

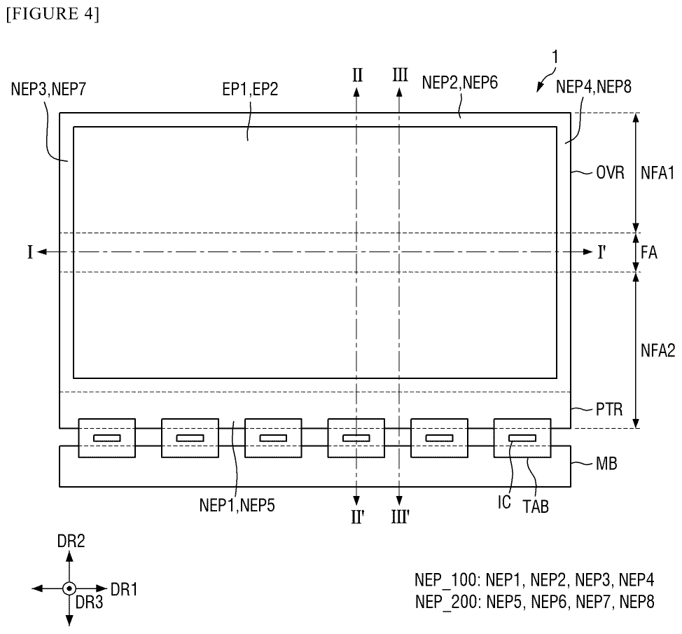

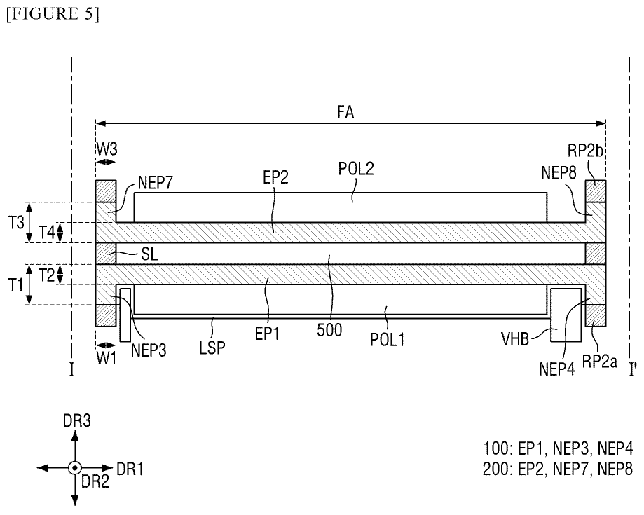

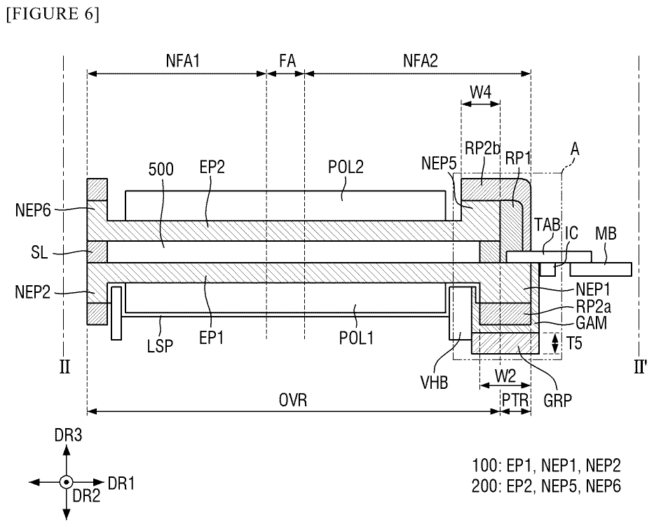

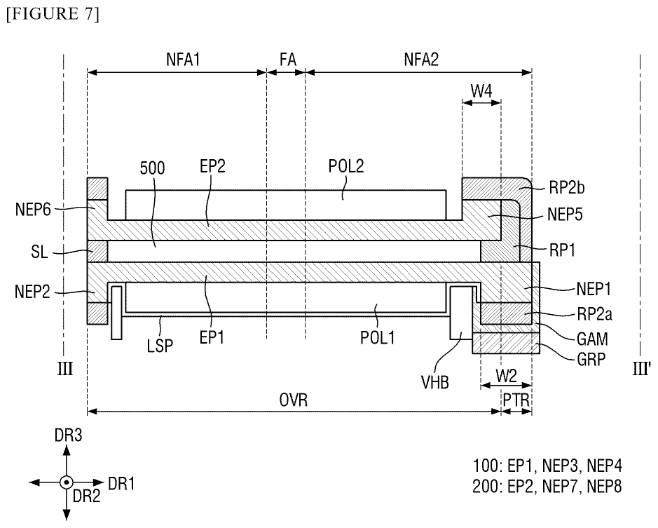

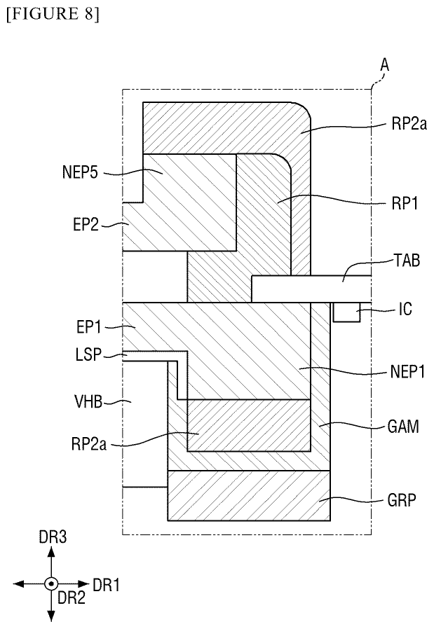

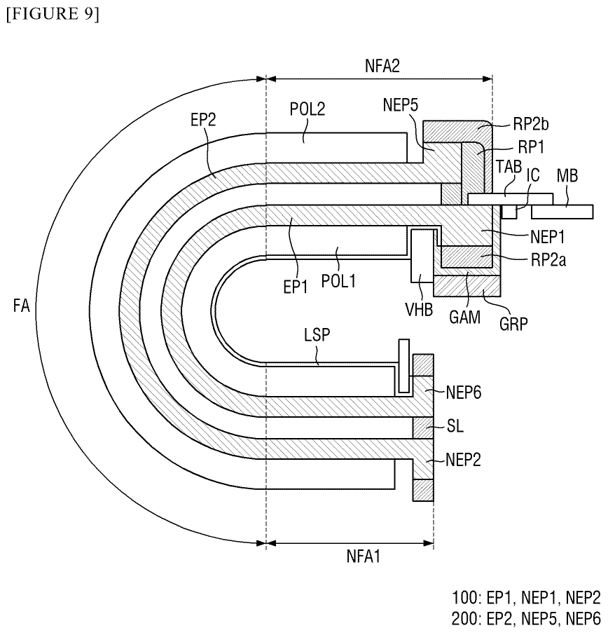

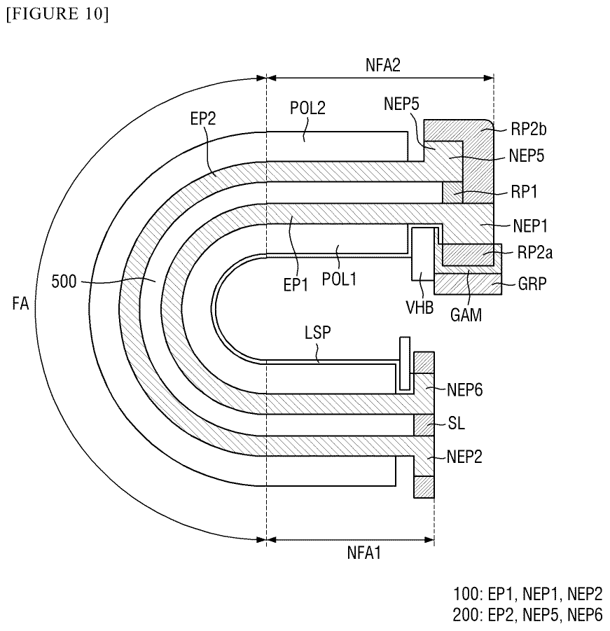

FIG. 1 is a plan view of a display device according to an exemplary embodiment. FIG. 2 is a plan view illustrating in detail a first substrate, a driving connection film, and a driving circuit board of the display device according to FIG. 1. FIG. 3 is a plan view illustrating in detail a second substrate of the display device according to FIG. 1. FIG. 4 is a plan view illustrating in detail the display device according to FIG. 1. FIG. 5 is a cross-sectional view taken along line I-I′ of FIG. 4. FIG. 6 is a cross-sectional view taken along line II-II′ of FIG. 4. FIG. 7 is a cross-sectional view taken along line III-III′ of FIG. 4. FIG. 8 is an enlarged cross-sectional view of area A of FIG. 6. FIGS. 9 and 10 are cross-sectional views illustrating a state in which the display device according to FIG. 1 is folded.

Referring to FIGS. 1 to 10, as long as a display device 1 is a device including a display area that displays an image or video, the display device 1 may be interpreted as a display device regardless of the main purpose, added functions or name, etc. of the device, For example, the display device 1 may include various home appliances, Internet of Things devices, etc. including a display unit, such as small gaming machines, large gaming machines such as slot machines used in casinos, electronic whiteboards, e-books, smartphones, mobile phones, tablet PCs, personal digital assistants (PDAs), portable multimedia players (PMPs), televisions, personal computer monitors, laptop computers, car navigations, car dashboards, digital cameras, camcorders, outdoor billboards, electronic signboards, various medical devices, various inspection devices, refrigerator, or washing machines, but is not limited to the above-mentioned examples.

In an embodiment, the display device 1 may have a rectangular shape including two opposing long sides (upper and lower sides when viewing a display surface in the drawing) and two opposing short sides (left and right sides when viewing the display surface in the drawing). Based on a direction of a normal display screen, the display device 1 may have the long sides disposed horizontally as illustrated in FIG. 1, but the long sides disposed vertically.

In the drawings, three directional axes are defined. A first direction DR1 may be a direction of extension of a long side of the display device, a second direction DR2 may be a direction of extension of a short side of the display device, and a third direction DR3 may be a direction of thickness of the display device. One side in the first direction DR1 may be defined as a right short side of the display device 1, the other side in the first direction DR1 may be defined as a left short side of the display device 1, one side in the second direction DR2 may be defined as an upper long side of the display device 1, and the other side in the second direction DR2 may be defined as a lower long side of the display device 1, but the above-mentioned definitions of the directional axes should be understood as relative.

A liquid crystal display (LCD) may be applied as the display device 1. In the following embodiments, an example in which a liquid crystal display is applied as the display device 1 will be described, but the display device 1 is not limited thereto and may also be applied to an electrophoretic display (EPD), an organic light emitting display (OLED), an inorganic EL display device, a plasma display (PDP), or a field emission display (FED).

The display device 1 may include a first substrate 100, a second substrate 200 opposite to the first substrate 100, and a liquid crystal layer 500 interposed between the first substrate 100 and the second substrate 200. A sealing member SL may be disposed on edges of the first substrate 100 and the second substrate 200 to couple the first substrate 100 and the second substrate 200 to each other and protect the liquid crystal layer 500 from the outside. One of the first substrate 100 and the second substrate 200 may be a thin film transistor substrate, and the other may be a color filter substrate. For example, the first substrate 100 may be a thin film transistor substrate, and the second substrate 200 may be a color filter substrate.

The first substrate 100 may relatively more protrude than the second substrate 200. For example, the other end of the first substrate 100 in the second direction DR2 may more protrude than the other end of the second substrate 200 in the second direction DR2. In the following, an area protruding from the other side of the first substrate 100 in the second direction DR2 compared to the second substrate 200 may be defined as a protruding area PTR of the first substrate 100, and in the thickness direction, an area where the first substrate 100 and the second substrate 200 overlap may be defined as an overlapping area OVR of the first substrate 100.

The protruding area PTR may not be disposed to overlap the second substrate 200. A driver for driving the first substrate 100 may be disposed or attached on the protruding area PTR of the first substrate 100. For example, the driver may include a driving connection film TAB and a driving circuit board MB connected thereto, and among them, the driving connection film TAB may be attached on the protruding area PTR of the first substrate 100. The second substrate 200 may include one surface facing the first substrate 100 and the other surface being an opposite surface of the one surface. Similarly, the first substrate 100 may include one surface facing the second substrate 200 and the other surface being an opposite surface of the one surface. A display direction may be a direction viewing from one surface of the second substrate 200 to the other surface thereof.

The driving connection film TAB may be attached onto one surface of the first substrate 100. A driving chip (IC) may be disposed on the driving connection film TAB.

In an embodiment, each of the first substrate 100 and the second substrate 200 may include an insulating substrate made of glass, quartz, or the like, and structures such as a wiring, a metal, a semiconductor layer, an insulating film, a color filter, and a black matrix disposed thereon. The structures may be disposed on surfaces of the insulating substrate of the first substrate 100 and the insulating substrate of the second substrate 200 facing each other, respectively. One surface of the insulating substrate of the first substrate 100 and the insulating substrate of the second substrate 200 are each flat, but the other surface (or back surface), which is the opposite surface, may include areas that are protruded or recessed by slimming, for example, etching or polishing. In the drawing, for convenience, the illustration of the structures disposed on the insulating substrates is omitted, and only the shapes of the insulating substrates of the first substrate 100 and the second substrate 200 are illustrated. Hereinafter, when referring to the shape of the other surface (back surface) of the first substrate 100 or the second substrate 200, such a shape may refer to a shape of the back surface of the insulating substrate of the first substrate 100 or a shape of the back surface of the insulating substrate of the second substrate 200. However, the embodiment is not limited to the above-mentioned example, and another additional layer may be disposed on the back surface of the insulating substrate of the first substrate 100 or the second substrate 200, and the corresponding layer may also include an area that is protruded or recessed, such as by slimming.

The driving connection film TAB serves to connect the first substrate 100 and the driving circuit board MB or the main circuit board or the main circuit board. The driving connection film TAB may be attached onto one surface of the first substrate 100 by interposing a conductive anisotropic film therebetween. However, the driving connection film TAB is not limited thereto, and may also be directly attached onto one surface of the first substrate 100 through soldering or ultrasonic bonding. The driving connection film TAB is a film including a signal line and may be formed by including a flexible film. That is, the drive connection film TAB may be a flexible printed circuit board (FPC), a tab, or a connect film.

The driving circuit board MB may be attached to one end of the driving connection film TAB. The driving connection film TAB and the driving circuit board MB may be attached by the conductive anisotropic film interposed therebetween. When soldering or ultrasonic bonding is used to couple the driving connection film TAB and the driving circuit board MB, a second conductive anisotropic film may be omitted.

The driving circuit board MB may be made of a printed circuit board (PCB).

In the drawing, a case in which the driving circuit board MB and the driving connection film TAB connecting the same are disposed on the other end of the first substrate 100 in the second direction DR2 is illustrated, but the driving circuit board MB and the driving connection film TAB may be disposed on one end of the first substrate 100 in the second direction DR2, or on one or the other end thereof in the first direction DR1. In some embodiments, a plurality of driving connection films TAB may be provided. The plurality of driving connection films TAB may be arranged to be spaced apart from each other along the first direction DR1. At least one drive circuit board MB may be connected to the other end of each of the plurality of drive connection films TAB in the second direction DR2.

Meanwhile, the first substrate 100 according to an embodiment may include a lower slimming portion EP1 and a lower non-slimming portion NEP_100 surrounding the lower slimming portion EP1 in plan view, and the second substrate 200 may include an upper slimming portion EP2 and an upper non-slimming portion NEP_200 surrounding the upper slimming portion EP2 in plan view. In an embodiment, an area of the upper slimming portion EP2 in plan view may be smaller than an area of the lower slimming portion EP1 in plan view. A thickness of the upper non-slimming portion NEP_200 may be greater than a thickness of the upper slimming portion EP2. In other words, the thickness of the upper slimming portion EP2 may be smaller than the thickness of the upper non-slimming portion NEP_200.

A thickness of the lower non-slimming portion NEP_100 may be greater than a thickness of the lower slimming portion EP1. In other words, the thickness of the lower slimming portion EP1 may be smaller than the thickness of the lower non-slimming portion NEP_100.

The lower non-slimming portion NEP_100 may include a first non-slimming portion NEP1 positioned on the other side of the lower slimming portion EP1 in the second direction DR2, a second non-slimming portion NEP2 positioned on one side thereof in the second direction DR2, a third non-slimming portion NEP3 positioned on the other side thereof in the first direction DR1, and a fourth non-slimming portion NEP4 positioned on one side thereof in the first direction DR1 in plan view.

The lower slimming portion EP1 may have a line shape extending along the first direction DR1. In plan view, the lower slimming portion EP1 may have a rectangular shape. The planar shape of the lower slimming portion EP1 may have a long side extending along the first direction DR1 and a short side extending along the second direction DR2.

The upper slimming portion EP2 may have a line shape extending along the first direction DR1. In plan view, the upper slimming portion EP2 may have a rectangular shape. The planar shape of the upper slimming portion EP2 may have a long side extending along the first direction DR1 and a short side extending along the second direction DR2.

The upper non-slimming portion NEP_200 may include a fifth non-slimming portion NEP5 positioned on the other side of the upper slimming portion EP2 in the second direction DR2, a sixth non-slimming portion NEP6 positioned on one side thereof in the second direction DR2, a seventh non-slimming portion NEP7 positioned on the other side thereof in the first direction DR1, and an eighth non-slimming portion NEP8 positioned on one side thereof in the first direction DR1 in plan view.

The overlapping area OVR may include a portion of the first non-slimming portion NEP1 of the first substrate 100, the non-slimming portions NEP2, NEP3, and NEP4, and the lower slimming portion EP1.

The protruding area PTR may include another portion of the first non-slimming portion NEP1.

Meanwhile, in the display device 1 according to an embodiment, a folding area FA and non-folding areas NFA1 and NFA2 may be defined. The folding area FA may extend along the first direction DR1, and a first non-folding area NFA1 may be positioned on one side of the folding area FA in the second direction DR2, and a second non-folding area NFA2 may be positioned on the other side of the folding area FA in the second direction DR2.

The folding area FA may include a central portion of the lower slimming portion EP1 (based on the second direction DR2), central portions of the non-slimming portions NEP3 and NEP4 (based on the second direction DR2), a central portion of the upper slimming portion EP2 (based on the second direction DR2), and central portions of the non-slimming portions NEP7 and NEP8 (based on the second direction DR2).

The first non-folding area NFA1 may include one side portion of the lower slimming portion EP1 in the second direction DR2, one side portions of the non-slimming portions NEP3 and NEP4 in the second direction DR2, the second non-slimming portion NEP2, one side portion of the upper slimming portion EP2 in the second direction DR2, one side portions of the non-slimming portions NEP7 and NEP8 in the second direction DR2, and the sixth non-slimming portion NEP6.

The second non-folding area NFA2 may include the other side portion of the lower slimming portion EP1 in the second direction DR2, the other side portions of the non-slimming portions NEP3 and NEP4 in the second direction DR2, the first non-slimming portion NEP1, the other side portion of the upper slimming portion EP2 in the second direction DR2, the other side portions of the non-slimming portions NEP7 and NEP8 in the second direction DR2, and the fifth non-slimming portion NEP5.

The display device 1 may be folded (or bent) based on the folding area FA described above. That is, as illustrated in FIGS. 9 and 10, respectively, in the folded state of the display device 1, the other surface of the first substrate 100 of the first non-folding area NFA1 and the other surface of the second substrate 200 of the second non-folding area NFA2 may face each other.

The non-folding areas NFA1 and NFA2 excluding the folding area FA may remain in a non-folding state without being folded.

The folding area FA may be folded with a predetermined curvature. A side surface of the folding area FA folded with the predetermined curvature may have a curved shape. The non-folding areas NFA1 and NFA2, which are distinct from the folding area FA, may not be folded. Side surfaces of the non-folding areas NFA1 and NFA2 that are not folded may have a straight shape.

In the folding area FA, the substrates 100 and 200 may have a predetermined radius of curvature from a center point. In FIGS. 9 and 10, the radius of curvature of the first substrate 100 may be smaller than the radius of curvature of the second substrate 200.

As illustrated in FIG. 4, the lower slimming portion EP1 may have a second thickness T2, the non-slimming portions NEP3 and NEP4 may have a first thickness T1, the upper slimming portion EP2 may have a fourth thickness T4, and the non-slimming portions NEP7 and NEP8 may have a third thickness T3. The first thickness T1 may be greater than the second thickness T2, and the third thickness T3 may be greater than the fourth thickness T4. The non-slimming portions NEP1 and NEP2 of the first substrate 100 excluding the third and fourth non-slimming portions NEP3 and NEP4 may also have the first thickness T1, and the non-slimming portions NEP5 and NEP6 of the second substrate 200 excluding the seventh and eighth non-slimming portions NEP7 and NEP8 may also have the third thickness T3.

The second thickness T2 may be equal to the fourth thickness T4, and the first thickness T1 may be equal to the third thickness T3, but is not limited thereto.

The second thickness T2 may be, but is not limited to, about 0.1 to about 0.8 times the first thickness T1, or about 0.4 to 0.6 times the first thickness T1. Similarly, the fourth thickness T4 may be, but is not limited to, about 0.1 to about 0.8 times the third thickness T3, or about 0.4 to 0.6 times the third thickness T3.

In this way, since the slimming portions EP1 and EP2 have a thinner thickness than the non-slimming portions NEP_100 and NEP_200, the corresponding area may be curved well during the curved process.

The non-slimming portions NEP2 to NEP4 of the non-slimming portion NEP_100 of the first substrate 100 may have a first width W1, and the first non-slimming portion NEP1 thereof may have a second width W2. The second width W2 may be greater than the first width W1. A portion corresponding to the first width W1 of the first non-slimming portion NEP1 may be disposed in the above-described overlapping area OVR, and an extending portion compared to the first width W1 may be disposed in the protruding area PTR. The non-slimming portions NEP6 to NEP8 of the non-slimming portion NEP_200 of the second substrate 200 may have a third width W3, and the fifth non-slimming portion NEP5 thereof may have a fourth width W4. The fourth width W4 may be greater than the third width W3.

Meanwhile, as illustrated in FIGS. 5 to 7, the display device 1 may further include polarizing films POL1 and POL2. A first polarizing film POL1 may be attached onto the other surface of the first substrate 100, and a second polarizing film POL2 may be attached onto the other surface of the second substrate 200. The attachment areas of the polarizing film POL1 and POL2 may be within the slimming portions EP1 and EP2 of each substrate 100 and 200, but are not limited thereto.

Meanwhile, the display device 1 according to an embodiment may further include a light blocking tape LSP disposed on the other surface of the first substrate 100, a coupling member VHB on a light blocking tape LSP, a first resin RP1, second resins RP2a and RP2b, a glass coupling agent GAM, and a reinforcing member GRP.

The first resin RP1 may be disposed on the outer side of the fifth non-slimming portion NEP5 of the second substrate 200. The first resin RP1 may overlap the driving connection film TAB in the thickness direction. The first resin RP1 may be disposed on the protruding portion PTR of the second non-folding area NFA2 and may be in contact with an outer side surface of the fifth non-slimming portion NEP5 and an outer side surface of the sealing member SL, respectively. The first resin RP1 may be in direct contact with an upper surface of the driving connection film TAB.

In an embodiment, the first resin RP1 may be formed of a material having acid resistance. For example, the first resin RP1 may include a silicone resin, an acrylic resin, an epoxy resin, a phenolic resin, a polyamides resin, a polyimides resin, an unsaturated polyesters resin, a poly phenylenes resin, a poly phenylenesulfides resin, benzocyclobutene (BCB), or the like.

When the slimming process is performed as an etching process as the first resin RP1 is formed of the material having acid resistance, it is possible to prevent the etchant from damaging the sealing member SL on the other side of the display device 1 in the second direction DR2.

The second resins RP2a and RL2b may be disposed on the first substrate 100 and the second substrate 200. In an embodiment, the second resins RP2a and RP2b may be formed of a material having acid resistance. For example, the second resins RP2a and RP2b may include a silicone resin, an acrylic resin, an epoxy resin, a phenolic resin, a polyamides resin, a polyimides resin, an unsaturated polyesters resin, a poly phenylenes resin, a poly phenylenesulfides resin, benzocyclobutene (BCB), or the like. The second resins RP2a and RL2b may include an ultraviolet curable material. The second resins RP2a and RL2b may serve as a masking for the non-slimming portions NEP_100 and NEP_200 when performing the slimming process.

The second resins RP2a and RL2b may include a second lower resin RP2a on the first substrate 100 and a second upper resin RP2b on the second substrate 200.

The second lower resin RP2a may be disposed on the non-slimming portion NEP_100 of the first substrate 100. The second lower resin RP2a may be disposed to overlap the non-slimming portion NEP_100 of the first substrate 100 in the thickness direction. A width of the second lower resin RP2a may be the same as a width of the non-slimming portion NEP_100 (NEP1 to NEP4) overlapping the second lower resin RP2a.

The second upper resin RP2b may be disposed on the non-slimming portion NEP_200 of the second substrate 200. The second upper resin RP2b may be disposed to overlap the non-slimming portion NEP_200 of the second substrate 200 in the thickness direction. A width of the second upper resin RP2b may be approximately the same as a width of the non-slimming portion NEP_200 overlapping the second upper resin RP2b. However, the width of the second upper resin RP2b overlapping the fifth non-slimming portion NEP5 may be greater than a width of the fifth non-slimming portion NEP5. For example, the second upper resin RP2b overlapping the fifth non-slimming portion NEP5 may overlap the fifth non-slimming portion NEP5 and the first resin RP1 disposed on the outer side surface of the fifth non-slimming portion NEP5. Furthermore, the second upper resin RP2b may be in direct contact with the upper surface and outer side surface of the first resin RP1. The second upper resin RP2b may also be in direct contact with the upper surface of the driving connection film TAB.

The light blocking tape LSP may be disposed on the lower surface of the first substrate 100. The light blocking tape LSP may be disposed on the other surface of the first substrate 100 exposed by the first polarizing film POL1 and on the first polarizing film POLL. The light blocking tape LSP may serve to prevent light traveling in a downward direction (the other direction in the third direction DR3) of light generated from the first substrate 100 from traveling to the outside.

The light blocking tape LSP may be in contact with an inner side surface of the first non-slimming portion NEP1 of the first substrate 100, an inner side surface of the second non-slimming portion NEP2, an inner side surface of the third non-slimming portion NEP3, an inner side surface of the fourth non-slimming portion NEP4, the other surface of the lower slimming portion EP1 exposed by the first polarizing film POL1, and the side and lower surfaces of the first polarizing film POL1, respectively.

A double-sided tape VHB for attaching a panel bracket (not illustrated) on a lower side of the first substrate 100 may be further disposed on the lower side of the light blocking tape LSP. The double-sided tape VHB may be disposed on the other surface of the lower slimming portion EP1 exposed by the first polarizing film POLL. The double-sided tape VHB may include a first substrate, a first adhesive layer on an upper side of the first substrate, and a second adhesive layer on a lower side of the first substrate. The first substrate may include a plastic material, etc., the first adhesive layer may be coupled to the light blocking tape LSP disposed on the other surface of the lower slimming portion EP1 exposed by the first polarizing film POL1, and the second adhesive layer may be coupled to the panel bracket.

An adhesive member GAM may be disposed on the second lower resin RP2a. The adhesive member GAM may be a glass adhesive. The adhesive member GAM may include a glass composition. For example, the glass composition may include various compositions known in the art. In an embodiment, the glass composition may include a LAS glass ceramic containing lithium aluminosilicate.

The adhesive member GAM may include, but is not limited to, the same material as the insulating substrate of the first substrate 100. A width of the adhesive member GAM in the first direction DR1 may be greater than the width W2 of the first non-slimming portion NEP1. The adhesive member GAM may be in direct contact with the light blocking tape LSP on the inner side surface of the first non-slimming portion NEP1, the inner side surface, the outer side surface, and the lower surface of the second lower resin RP2a, and the outer side surface of the first non-slimming portion NEP1. The adhesive member GAM may also be in direct contact with the lower surface of the driving connection film TAB. However, the adhesive member GAM may not overlap the driving chip (IC) mounted on the driving connection film TAB in the thickness direction. That is, the adhesive member GAM may not overlap the driving chip (IC) in the thickness direction in a state in which the driving connection film TAB is unfolded as illustrated in FIG. 6. The reason why the adhesive member GAM is disposed so as not to overlap the driving chip (IC) in the thickness direction in the state in which the driving connection film TAB is unfolded is that, although the driving connection film TAB is not illustrated, the driving connection film TAB is bent onto the other surface of the first substrate 100. When the adhesive member GAM is disposed to overlap the driving chip (IC) in the thickness direction in the state in which the driving connection film TAB is unfolded, the bending of the driving connection film TAB onto the other surface of the first substrate 100 may be difficult. According to an embodiment, as the adhesive member GAM is disposed on an inner side of the driving chip (IC) in plan view without overlapping the driving chip (IC) in the thickness direction in the state in which the driving connection film TAB is unfolded, there is an advantage in that it is possible to easily bend the driving connection film TAB onto the other surface of the first substrate 100.

Meanwhile, the inner side surface of the first non-slimming portion NEP1 of the first substrate 100 of the display device 1 according to an embodiment may be positioned further outward than the inner side surface of the fifth non-slimming portion NEP5 of the second substrate 200. In other words, the inner side surface of the fifth non-slimming portion NEP5 of the second substrate 200 may be positioned further inward than the inner side surface of the first non-slimming portion NEP1 of the first substrate 100. In plan view, the outer side surface of the fifth non-slimming portion NEP5 of the second substrate 200 may be disposed between the inner side surface of the first non-slimming portion NEP1 of the first substrate 100 and the outer side surface of the first non-slimming portion NEP1 of the first substrate 100. For example, when a physical impact is applied from the outside to the outer side surface of the fifth non-slimming portion NEP5 of the second substrate 200, the physical impact applied to the outer side surface of the fifth non-slimming portion NEP5 may be provided to a boundary between the inner side surface of the first non-slimming portion NEP1 of the first substrate 100 and the lower slimming portion EP1 adjacent to each other. The boundary between the inner side surface of the first non-slimming portion NEP1 of the first substrate 100 and the lower slimming portion EP1 may be a portion that is very vulnerable to external impact. When the physical impact applied to the outer side surface of the fifth non-slimming portion NEP5 is provided to the boundary between the inner side surface of the first non-slimming portion NEP1 of the first substrate 100 and the lower slimming portion EP1, which is the portion that is very vulnerable to external impact, cracks may occur at the boundary.

However, according to an embodiment, as the adhesive member GAM is disposed so that the width thereof in the first direction DR1 is greater than the width W2 of the first non-slimming portion NEP1, and is disposed to be in direct contact with the light blocking tape LSP on the inner side surface of the first non-slimming portion NEP1, the inner side surface, the outer side surface, and lower surface of the second lower resin RP2a, and the outer side surface of the first non-slimming portion NEP1, the adhesive member GAM may cover the boundary between the inner side surface of the first non-slimming portion NEP1 of the first substrate 100 and the lower slimming portion EP1, which is a portion that is very vulnerable to external impact.

As a result, since it is possible to prevent in advance the physical impact applied to the outer side surface of the fifth non-slimming portion NEP5 from being applied to the boundary between the inner side surface of the first non-slimming portion NEP1 of the first substrate 100 and the lower slimming portion EP1 adjacent to each other, cracks, etc. may be prevented from occurring in advance at the boundary between the inner side surface of the first non-slimming portion NEP1 of the first substrate 100 and the lower slimming portion EP1, which is a portion that is very vulnerable to external impact, thereby enhancing the durability of the display device 1. Furthermore, as described above, since the adhesive member GAM is not only disposed on the inner side surface of the first non-slimming portion NEP1, but also on the outer side surface and the lower surface of the first non-slimming portion NEP1, the adhesive member GAM may protect the entire area of the first non-slimming portion NEP1 from the external impact.

Meanwhile, the display device 1 according to an embodiment may further include a reinforcing member GRP having greater strength than the adhesive member GAM to supplement the above-described adhesive member GAM. The reinforcing member GRP may be disposed on a lower side of the adhesive member GAM. The reinforcing member GRP may have greater strength than the adhesive member GAM. To enable the reinforcing member GRP to have greater strength than the adhesive member GAM, the reinforcing member GRP may include a reinforced glass product. The reinforced glass product of the reinforcing member GRP may include a glass composition similarly to the adhesive member GAM described above. The reinforcement of the reinforcing member GRP may be achieved through, but is not limited to, chemical reinforcement.

The glass composition of the reinforcing member GRP may contain SiO₂ in the content of 50 to 80 mol %, Al₂O₃ in the content of 1 to 30 mol %, B₂O₃ in the content of 0 to 5 mol %, P₂O₅ in the content of 0 to 4 mol %, Li₂O in the content of 3 to 20 mol %, Na₂O in the content of 0 to 20 mol %, K₂O in the content of 0 to 10 mol %, MgO in the content of 3 to 20 mol %, CaO in the content of 0 to 20 mol %, SrO in the content of 0 to 20 mol %, BaO in the content of 0 to 15 mol %, ZnO in the content of 0 to 10 mol %, TiO₂ in the content of 0 to 1 mol %, and ZrO₂ in the content of 0 to 8 mol %. Here, “content of 0 mol %” means substantially not containing the corresponding component. A composition that is “substantially not containing” a particular component means that it is not intentionally included in the raw materials, etc., and includes a case where trace amounts of impurities, such as 0.1 mol % or less, are unavoidably contained.

Each component of the glass composition of the reinforcing member GRP will be described in more detail. SiO₂ may serve to constitute a skeleton of glass, increase chemical durability, and reduce an occurrence of cracks when scratches (indentations) occur on a glass surface. To sufficiently perform the above-mentioned role, SiO₂ may be included in the content of 50 mol % or more. To exhibit sufficient melting properties, the content of SiO₂ in the glass composition may be 80 mol % or less.

Al₂O₃ serves to improve friability of glass. That is, Al₂O₃ may serve to generate a smaller number of fragments when glass breaks. In addition, Al₂O₃ may act as an effective component to improve ion exchange performance during chemical enforcement and to increase surface compressive stress after enforcement. When the content of Al₂O₃ is 1 mol % or more, the above-mentioned functions may be effectively performed. Meanwhile, in order to maintain the acid resistance and melting property of the glass, it is desirable that the content of Al₂O₃ be 30 mol % or less.

B₂O₃ improves a chipping resistance of glass and improves melting properties thereof. B₂O₃ may be omitted (0 mol %), but may further improve the melting properties of the glass when contained at 0.5 mol % or more. The content of B₂O₃ of 5 mol % or less may be advantageous in suppressing the occurrence of streaks during melting.

P₂O₅ improves ion exchange performance and chipping resistance. P₂O₅ may be omitted (0 mol %), but may significantly perform the above-mentioned functions when contained at 0.5 mol % or more. P₂O₅ having the content of 4 mol % or less helps prevent significant deterioration in friability and acid resistance.

Li₂O serves to form surface compressive stress through ion exchange. Li ions disposed near the glass surface may be exchanged with Ka ions, etc. through an ion exchange process. However, the amount of Li ions exchanged for Ka ions may be significantly smaller than the amount of Na ions exchanged for Ka ions. Li₂O may also serve to improve the friability of glass.

Na₂O serves to form surface compressive stress through ion exchange and improve the melting properties of glass. Na ions disposed near the glass surface may be exchanged with K ions, etc. through an ion exchange process. The content of Na ions may be in the range of 10 to 15 wt %. In the forming step (S1), Na ions may be dispersed throughout the glass.

K₂O improves ion exchange performance and is related to friability. K₂O may be omitted, but may be contained in the content of 0.5 mol % or more to improve the ion exchange performance. The content of K₂O to prevent excessive reduction in friability may be 10 mol % or less.

MgO serves to increase the surface compressive stress of chemically enforced glass and improve friability thereof. The above-mentioned functions may be effectively performed when MgO has the content of 3 mol % or more. The content of MgO having a value of 20 mol % or less is advantageous in reducing the possibility of devitrification occurrence during glass melting.

CaO improves the melting properties of glass and improves friability thereof. CaO may be omitted, and it is desirable to have the content of 0.5 mol % or more to effectively perform the above-mentioned functions. Since the ion exchange performance may deteriorate when the content of CaO is too large, it is preferable that the content of CaO have a value of 20 mol % or less.

Similarly to CaO, SrO improves the melting properties of glass and improves friability thereof. SrO may be omitted, and it is desirable to have the content of 0.5 mol % or more to effectively perform the above-mentioned functions. Since the ion exchange performance may deteriorate when the content of SrO is too large, it is preferable that the content of SrO have a value of 20 mol % or less.

BaO improves the melting properties of glass and improves friability thereof. BaO may be omitted, and it is desirable to have the content of 0.5 mol % or more to effectively perform the above-mentioned functions. The content of BaO of 15 mol % or less may be advantageous in preventing excessive deterioration of the ion exchange performance.

ZnO serves to improve the melting properties of glass. ZnO may be omitted, and may exhibit a significant improvement in melting properties according to the content thereof when having the content of 0.25 mol % or more. To prevent deterioration of weather resistance, it is desirable to maintain the content of ZnO at 10 mol % or less.

TiO₂ improves the friability of chemically enforced glass. TiO₂ may be omitted, and when TiO₂ has the content of 0.1 mol % or more, it may exhibit a significant improvement in friability according to the content thereof. In order to prevent the devitrification phenomenon during melting, it is desirable that the content of TiO₂ is 1 mol % or less.

ZrO₂ may increase surface compressive stress by ion exchange and improve the friability of glass. ZrO₂ may be omitted, and can effectively perform the above-mentioned functions when contained at 0.5 mol % or more. The content of ZrO₂ of 8 mol % or less may be advantageous in suppressing the devitrification phenomenon during melting.

The glass composition of the reinforcing member GRP may further include components such as Y₂O₃, La₂O₃, Nb₂O₅, Ta₂O₅, Gd₂O₃, etc. in addition to the components listed above, as needed.

The reinforcing member GRP may include the glass composition similar or identical to that of the adhesive member GAM and may also include the chemically reinforced glass product, thereby providing greater strength than the adhesive member GAM. Since the reinforcing member GRP has greater strength than the adhesive member GAM, the reinforcing member GRP has the advantages of further supplementing the characteristic that prevents in advance the physical impact applied to the outer side surface of the fifth non-slimming portion NEP5 from being provided to the boundary between the inner side surface of the first non-slimming portion NEP1 of the first substrate 100 and the lower slimming portion EP1 adjacent to each other, the characteristic that enhances the durability of the display device 1, and the characteristic of being able to protect the entire area of the first non-slimming portion NEP1 from external impact, which are the above-described characteristics of the adhesive member GAM.

Hereinafter, a method of fabricating of a display device 1 according to an embodiment will be described.

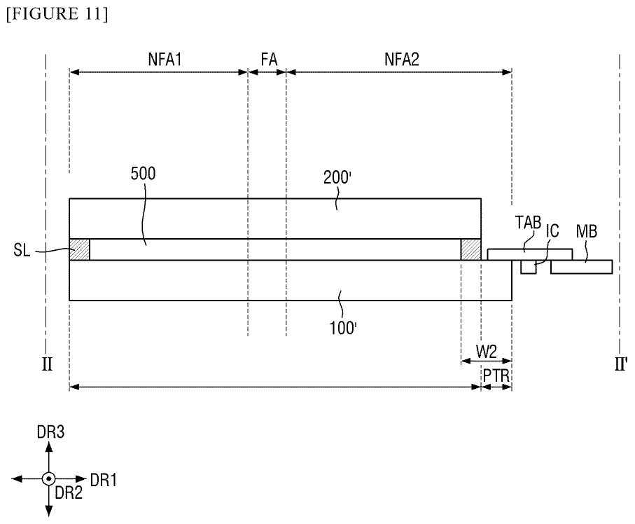

FIGS. 11 to 22 are cross-sectional views for each process of a method of fabricating a display device according to an embodiment. The same components as those of the previously described embodiments are denoted by the same reference numerals, and the descriptions thereof will be omitted or simplified.

While describing a method of fabricating a display device 1 according to an embodiment with reference to FIGS. 11 to 22, FIGS. 1 to 8 may be referred to together for convenience of explanation.

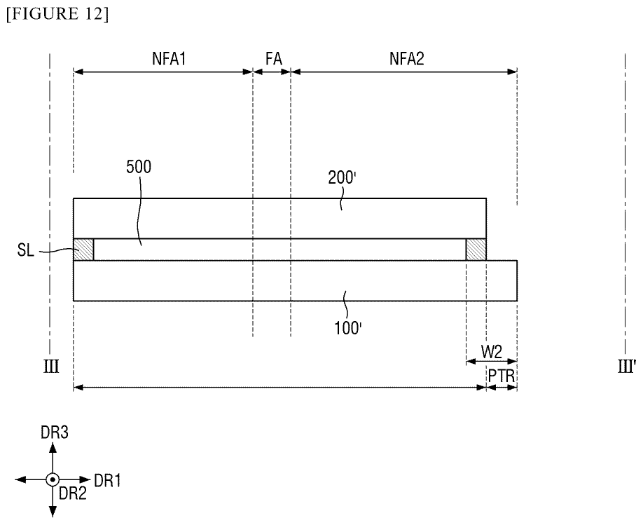

First, referring to FIGS. 11 and 12, as a step of preparing an upper target substrate 200′ and a lower target substrate 100′ facing the upper target substrate 200′, the upper target substrate 200′ and the lower target substrate 100′ are prepared, where the lower target substrate 100′ includes an overlapping portion OVR that overlaps the upper target substrate 200′ and a protruding portion PTR that protrudes outwardly more than the upper target substrate 200′. In the step of preparing the upper target substrate 200′ and the lower target substrate 100′, a liquid crystal layer 500 may be disposed between the lower target substrate 100′ and the upper target substrate 200′, and a sealing member SL may be disposed on edges of the lower target substrate 100′ and the upper target substrate 200′, thereby coupling the lower target substrate 100′ and the upper target substrate 200′ and protecting the liquid crystal layer 500 from the outside. One of the lower target substrate 100′ and the upper target substrate 200′ may be a thin film transistor substrate, and the other may be a color filter substrate. For example, the lower target substrate 100′ may be a thin film transistor substrate, and the upper target substrate 200′ may be a color filter substrate.

Next, a driving connection film TAB with a driving chip (IC) mounted thereon is disposed on the protruding portion PTR of the lower target substrate 100′. One end of the driving connection film TAB may be attached onto the protruding portion PTR, and the other end thereof may be connected to a driving circuit board MB.

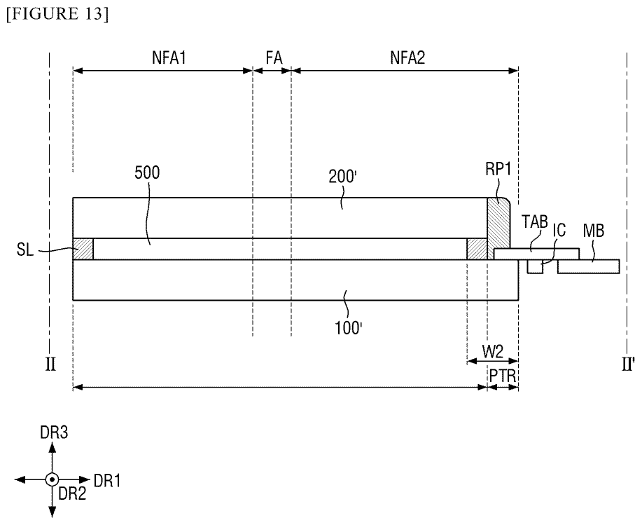

Next, as illustrated in FIG. 13, a first resin RP1 is disposed. The first resin RP1 may be disposed on one side of the upper target substrate 200′ (one side adjacent to the protruding portion PTR of the lower target substrate 100′). The first resin RP1 may overlap the driving connection film TAB in the thickness direction. The first resin RP1 may be disposed on the protruding portion PTR of the second non-folding area NFA2 and may be in contact with an outer side surface of the upper target substrate 200′ (one side surface adjacent to the protruding portion PTR of the lower target substrate 100′) and an outer side surface of the sealing member SL, respectively. The first resin RP1 may be in direct contact with an upper surface of the driving connection film TAB.

In an embodiment, the first resin RP1 may be formed of a material having acid resistance. For example, the first resin RP1 may include a silicone resin, an acrylic resin, an epoxy resin, a phenolic resin, a polyamides resin, a polyimides resin, an unsaturated polyesters resin, a poly phenylenes resin, a poly phenylenesulfides resin, benzocyclobutene (BCB), or the like.

When the slimming process is performed as an etching process, as the first resin RP1 is formed of the material having acid resistance, it is possible to prevent the etchant from damaging the sealing member SL on the other side of the display device in the second direction DR2.

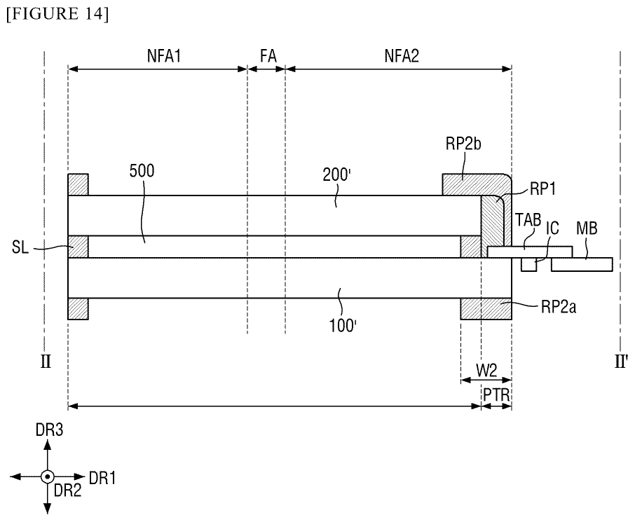

Next, as illustrated in FIG. 14, second resins RP2a and RP2b are disposed.

The second resins RP2a and RL2b may be disposed on the lower target substrate 100′ and the upper target substrate 200′. In an embodiment, the second resins RP2a and RP2b may be formed of a material having acid resistance. For example, the second resins RP2a and RP2b may include a silicone resin, an acrylic resin, an epoxy resin, a phenolic resin, a polyamides resin, a polyimides resin, an unsaturated polyesters resin, a poly phenylenes resin, a poly phenylenesulfides resin, benzocyclobutene (BCB), or the like. The second resins RP2a and RL2b may include an ultraviolet curable material. The second resins RP2a and RL2b may serve as a masking for the non-slimming portions (NEP_100 and NEP_200 in FIGS. 4 and 6 to 8) when performing the slimming process.

The second resins RP2a and RL2b may include a second lower resin RP2a on the lower target substrate 100′ and a second upper resin RP2b on the upper target substrate 200′.

The second lower resin RP2a may be disposed on the non-slimming portion (NEP_100 in FIGS. 4 and 6 to 8) of the lower target substrate 100′. The second lower resin RP2a may be disposed to overlap the non-slimming portion (NEP_100 in FIGS. 4 and 6 to 8) of the lower target substrate 100′ in the thickness direction. A width of the second lower resin RP2a may be the same as a width of the non-slimming portion NEP_100 (NEP1 to NEP4 in FIGS. 4 and 6 to 8) overlapping the second lower resin RP2a.

The second upper resin RP2b may be disposed on the non-slimming portion (NEP_200 in FIGS. 4 and 6 to 8) of the upper target substrate 200′. The second upper resin RP2b may be disposed to overlap the non-slimming portion (NEP_200 in FIGS. 4 and 6 to 8) of the upper target substrate 200′ in the thickness direction. A width of the second upper resin RP2b may be the same as a width of the non-slimming portion (NEP_200 in FIGS. 4 and 6 to 8) overlapping the second upper resin RP2b. However, a width of the second upper resin RP2b overlapping the fifth non-slimming portion (NEP5 in FIGS. 4 and 6 to 8) may be greater than the width of the fifth non-slimming portion (NEP5 in FIGS. 4 and 6 to 8). For example, the second upper resin RP2b overlapping the fifth non-slimming portion (NEP5 in FIGS. 4 and 6 to 8) may overlap the first resin RP1 disposed on the fifth non-slimming portion (NEP5 in FIGS. 4 and 6 to 8) and the outer side surface of the fifth non-slimming portion (NEP5 in FIGS. 4 and 6 to 8). Furthermore, the second upper resin RP2b may be in direct contact with the upper surface and outer side surface of the first resin RP1. The second upper resin RP2b may also be in direct contact with the upper surface of the driving connection film TAB.

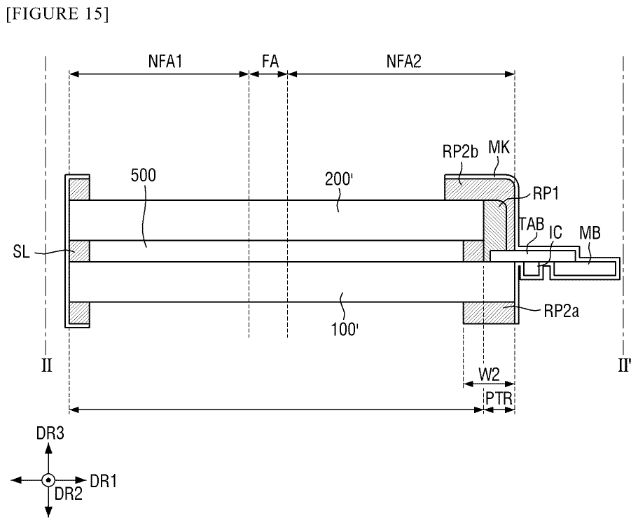

Next, as illustrated in FIG. 15, a masking member MK is disposed.

The masking member MK may be disposed on the non-slimming portions of the target substrates 100′ and 200′. That is, the masking member MK is disposed on the non-slimming portion (see NEP_100 and NEP_200 in FIGS. 4 and 6 to 8) of the target substrates 100′ and 200′, and may be further disposed to cover the entire area of the driving connection film TAB, the driving chip (IC), and the driving circuit board MB. In some embodiments, the masking member MK may be formed in a shape of an envelope with one end opened and may be installed in a form that covers a portion to be formed as the non-slimming portions (see NEP_100 and NEP_200 in FIGS. 4 and 6 to 8). As an example, the masking member MK is in the form of a film and may be pasted over from one surface to the other surface. An acid-resistant adhesive tape (not illustrated) may be installed on an edge of the masking member MK to facilitate attachment of the masking member MK to the attachment portion, and when the masking member MK is in the form of a film and is pasted by being turned, the masking member MK may be configured to prevent the permeation of the etchant of the slimming process by attaching both side ends that are pasted by being turned using the acid-resistant adhesive tape or by heat-melting. The masking member MK may itself be made of adhesive tape.

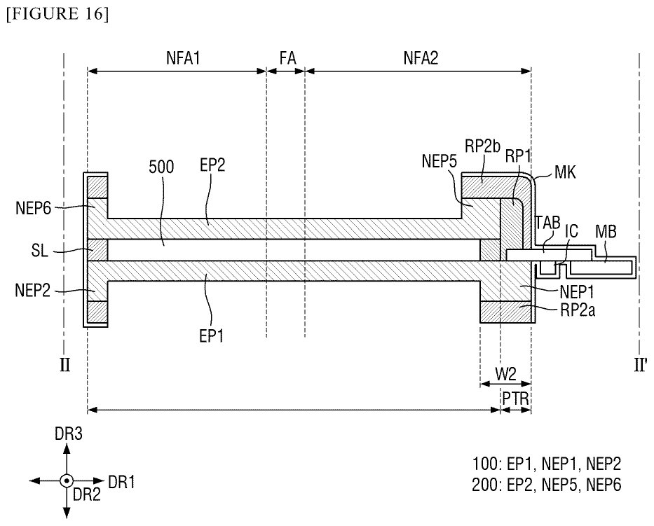

Next, as illustrated in FIG. 16, a slimming process is performed on the lower target substrate 100′ and the upper target substrate 200′. The slimming process may be a process of forming the slimming portions EP1 and EP2 of the substrates 100 and 200. The slimming process may be performed through an etching process using an etchant or a polishing process. The etching process may be performed through a wet etching process, and in order to prevent damage to structures, such as the circuit portion, on the insulating substrate of the lower target substrate 100′ by the etchant used in the wet etching process, the masking member MK, the first resin RP1, etc. described above may be disposed.

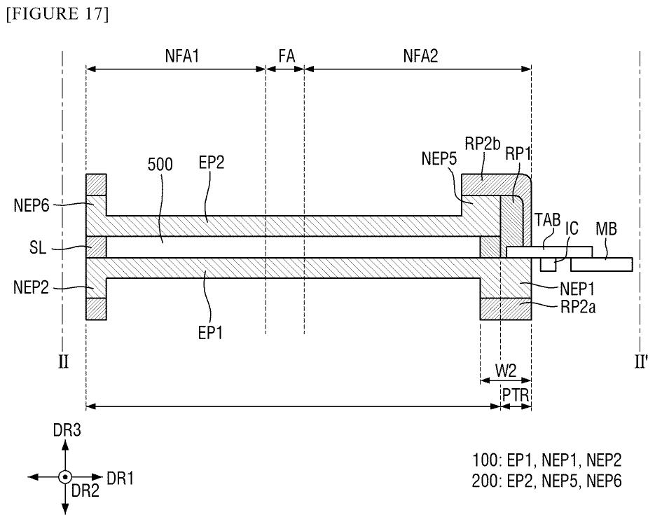

Next, as illustrated in FIG. 17, the masking member MK is removed.

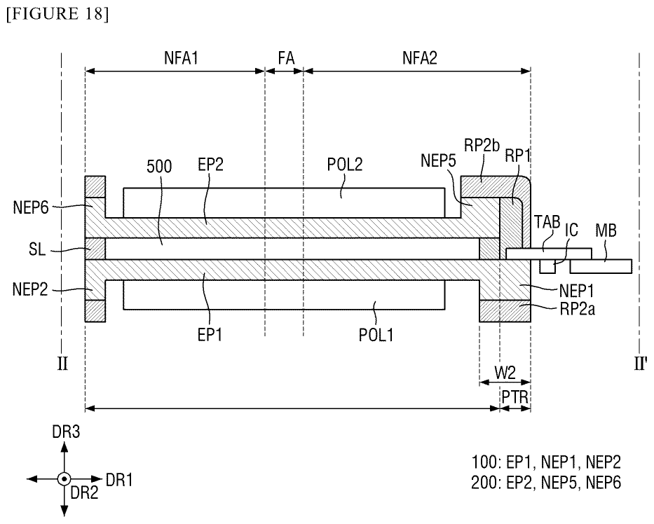

Next, as illustrated in FIG. 18, polarizing films POL1 and POL2 are disposed. A first polarizing film POL1 may be attached onto the other surface of the first substrate 100, and a second polarizing film POL2 may be attached onto the other surface of the second substrate 200. The attachment areas of the polarizing film POL1 and POL2 may be within the slimming portions EP1 and EP2 of each substrate 100 and 200, but are not limited thereto.

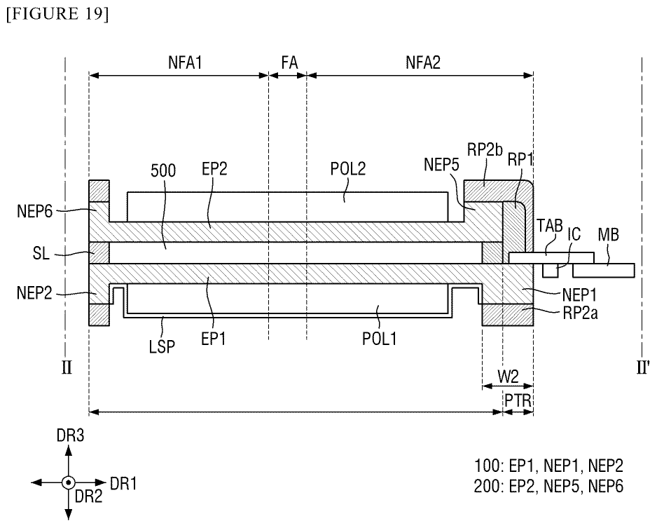

Next, as illustrated in FIG. 19, a light blocking tape LSP is disposed.

The light blocking tape LSP may be disposed on the lower surface of the first substrate 100. The light blocking tape LSP may be disposed on the other surface of the first substrate 100 exposed by the first polarizing film POL1 and on the first polarizing film POLL. The light blocking tape LSP may serve to prevent light traveling in a downward direction (the other direction in the third direction DR3) of light generated from the first substrate 100 from traveling to the outside.

The light blocking tape LSP may be in contact with an inner side surface of the first non-slimming portion NEP1 of the first substrate 100, an inner side surface of the second non-slimming portion NEP2, an inner side surface of the third non-slimming portion NEP3, an inner side surface of the fourth non-slimming portion NEP4, the other surface of the lower slimming portion EP1 exposed by the first polarizing film POL1, and the side and lower surfaces of the first polarizing film POL1, respectively.

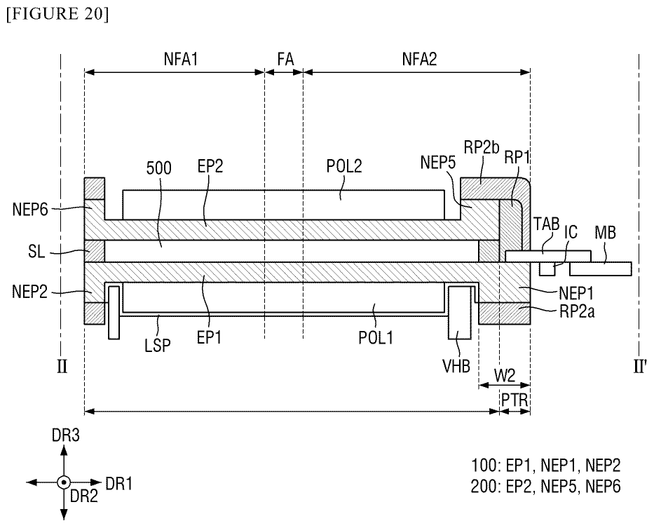

Next, as illustrated in FIG. 20, a double-sided tape VHB is disposed.

The double-sided tape VHB for attaching a panel bracket (not illustrated) on a lower side of the first substrate 100 may be further disposed on the lower side of the light blocking tape LSP. The double-sided tape VHB may be disposed on the other surface of the lower slimming portion EP1 exposed by the first polarizing film POLL. The double-sided tape VHB may include a first substrate, a first adhesive layer on an upper side of the first substrate, and a second adhesive layer on a lower side of the first substrate. The first substrate may include a plastic material, etc., the first adhesive layer may be coupled to the light blocking tape LSP disposed on the other surface of the lower slimming portion EP1 exposed by the first polarizing film POL1, and the second adhesive layer may be coupled to the panel bracket.

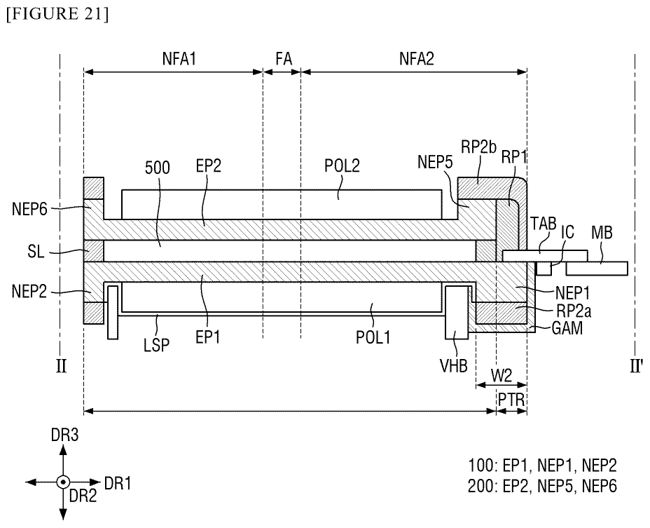

Next, as illustrated in FIG. 21, an adhesive member GAM is disposed.

An adhesive member GAM may be disposed on the second lower resin RP2a. The adhesive member GAM may be a glass adhesive. The adhesive member GAM may include a glass composition. For example, the glass composition may include various compositions known in the art. In an embodiment, the glass composition may include a LAS glass ceramic containing lithium aluminosilicate.

The adhesive member GAM may include, but is not limited to, the same material as the insulating substrate of the first substrate 100. The adhesive member GAM may be in direct contact with the light blocking tape LSP on the inner side surface of the first non-slimming portion NEP1, the inner side surface, the outer side surface, and the lower surface of the second lower resin RP2a, and the outer side surface of the first non-slimming portion NEP1. The adhesive member GAM may also be in direct contact with the lower surface of the driving connection film TAB. However, the adhesive member GAM may not overlap the driving chip (IC) mounted on the driving connection film TAB in the thickness direction. That is, the adhesive member GAM may not overlap the driving chip (IC) in the thickness direction in a state in which the driving connection film TAB is unfolded. The reason why the adhesive member GAM is disposed so as not to overlap the driving chip (IC) in the thickness direction in the state in which the driving connection film TAB is unfolded is that, although the driving connection film TAB is not illustrated, the driving connection film TAB is bent onto the other surface of the first substrate 100. When the adhesive member GAM is disposed to overlap the driving chip (IC) in the thickness direction in the state in which the driving connection film TAB is unfolded, the bending of the driving connection film TAB onto the other surface of the first substrate 100 may be difficult. According to an embodiment, as the adhesive member GAM is disposed on an inner side of the driving chip (IC) in plan view without overlapping the driving chip (IC) in the thickness direction in the state in which the driving connection film TAB is unfolded, there is an advantage in that it is possible to easily bend the driving connection film TAB onto the other surface of the first substrate 100.

Meanwhile, the inner side surface of the first non-slimming portion NEP1 of the first substrate 100 may be positioned further outward than the inner side surface of the fifth non-slimming portion NEP5 of the second substrate 200. In other words, the inner side surface of the fifth non-slimming portion NEP5 of the second substrate 200 may be positioned further inward than the inner side surface of the first non-slimming portion NEP1 of the first substrate 100. In plan view, the outer side surface of the fifth non-slimming portion NEP5 of the second substrate 200 may be disposed between the inner side surface of the first non-slimming portion NEP1 of the first substrate 100 and the outer side surface of the first non-slimming portion NEP1 of the first substrate 100. For example, when a physical impact is applied from the outside to the outer side surface of the fifth non-slimming portion NEP5 of the second substrate 200, the physical impact applied to the outer side surface of the fifth non-slimming portion NEP5 may be provided to a boundary between the inner side surface of the first non-slimming portion NEP1 of the first substrate 100 and the lower slimming portion EP1 adjacent to each other. The boundary between the inner side surface of the first non-slimming portion NEP1 of the first substrate 100 and the lower slimming portion EP1 may be a portion that is very vulnerable to external impact. When the physical impact applied to the outer side surface of the fifth non-slimming portion NEP5 is provided to the boundary between the inner side surface of the first non-slimming portion NEP1 of the first substrate 100 and the lower slimming portion EP1, which is the portion that is very vulnerable to external impact, cracks may occur at the boundary.

However, according to an embodiment, as the adhesive member GAM is disposed to be in direct contact with the light blocking tape LSP on the inner side surface of the first non-slimming portion NEP1, the inner side surface, outer side surface, and lower surface of the second lower resin RP2a, and the outer side surface of the first non-slimming portion NEP1, the adhesive member GAM may cover the boundary between the inner side surface of the first non-slimming portion NEP1 of the first substrate 100 and the lower slimming portion EP1, which is the portion that is very vulnerable to external impact.

As a result, since it is possible to prevent in advance the physical impact applied to the outer side surface of the fifth non-slimming portion NEP5 from being applied to the boundary between the inner side surface of the first non-slimming portion NEP1 of the first substrate 100 and the lower slimming portion EP1 adjacent to each other, cracks, etc. may be prevented from occurring in advance at the boundary between the inner side surface of the first non-slimming portion NEP1 of the first substrate 100 and the lower slimming portion EP1, which is a portion that is very vulnerable to external impact, thereby enhancing the durability of the display device 1. Furthermore, as described above, since the adhesive member GAM is not only disposed on the inner side surface of the first non-slimming portion NEP1, but also on the outer side surface and the lower surface of the first non-slimming portion NEP1, the adhesive member GAM may protect the entire area of the first non-slimming portion NEP1 from the external impact.

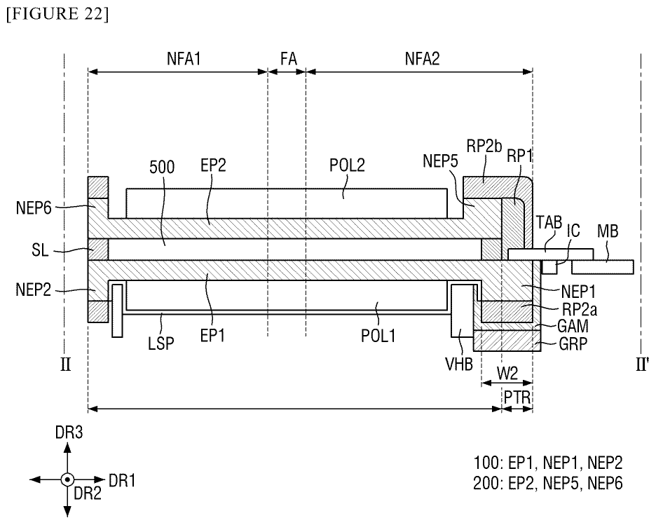

Next, as illustrated in FIG. 22, a reinforcing member GRP is disposed. The reinforcing member GRP may be disposed on a lower side of the adhesive member GAM. The reinforcing member GRP may have greater strength than the adhesive member GAM. To enable the reinforcing member GRP to have greater strength than the adhesive member GAM, the reinforcing member GRP may include a reinforced glass product. The reinforced glass product of the reinforcing member GRP may include a glass composition similarly to the adhesive member GAM described above. The reinforcement of the reinforcing member GRP may be achieved through, but is not limited to, chemical reinforcement. The exemplified material of the reinforcing member GRP is described above and a detailed description thereof will be omitted.

Hereinafter, other embodiments of the display device 1 will be described.

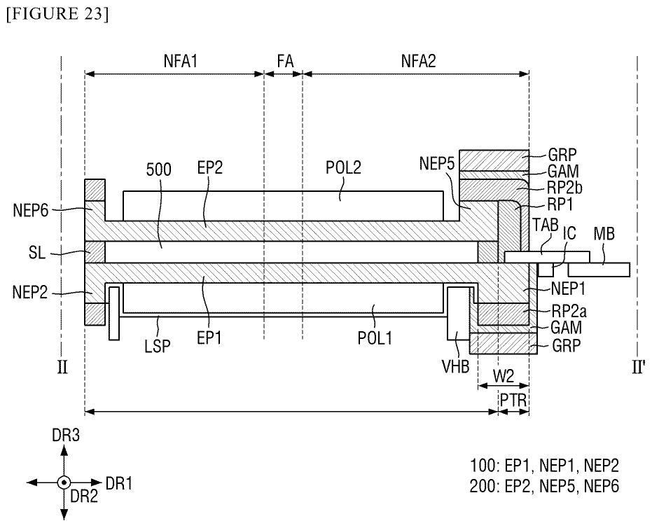

FIG. 23 is a cross-sectional view of a display device according to another embodiment.

Referring to FIG. 23, the display device according to the present embodiment is different from the display device according to the embodiment of FIG. 6, in that the adhesive member GAM and the reinforcing member GRP may each be further disposed on the second substrate 200. In the following, for convenience of explanation, the adhesive member GAM on the first substrate 100 is referred to as a lower adhesive and the reinforcing member GRP on the first substrate 100 is referred to as a lower reinforcing member, and the adhesive member GAM on the second substrate 200 is referred to as an upper adhesive and the reinforcing member GRP on the second substrate 200 is referred to as an upper reinforcing member.

The upper adhesive member GAM may be disposed on the second upper resin RP2b, and the upper reinforcing member GRP may be disposed on the upper adhesive member GAM. The material of the upper adhesive member GAM may include the same material as the exemplified material of the lower adhesive member GAM, and the material of the upper reinforcing member GRP may include the same material as the exemplified material of the lower reinforcing member GRP.

According to the present embodiment, because the upper adhesive member GAM is disposed on the second upper resin RP2b, when a physical impact is applied from the outside to the outer side surface of the fifth non-slimming portion NEP5 of the second substrate 200, the upper adhesive member GAM may cushion the physical impact, thereby preventing in advance the physical impact from being applied to the boundary between the inner side surface of the first non-slimming portion NEP1 of the first substrate 100 and the lower slimming portion EP1, which is a portion that is very vulnerable to external impact. Furthermore, since the upper reinforcing member GRP has greater strength than the upper adhesive member GAM, the characteristics of the upper adhesive member GAM may be further supplemented.

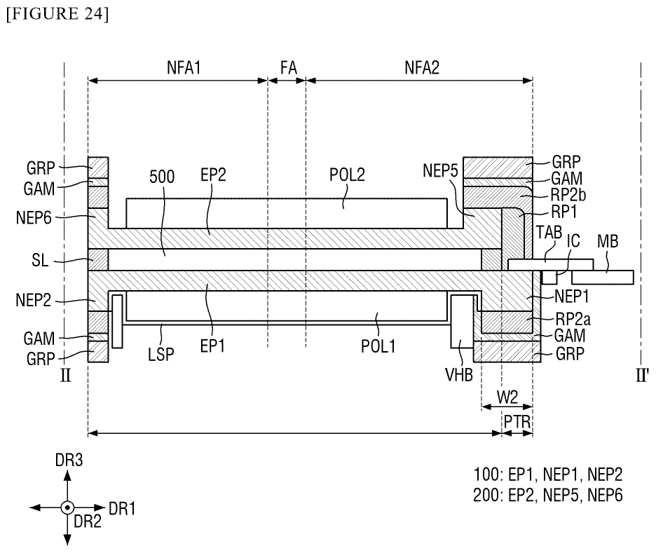

FIG. 24 is a cross-sectional view of a display device according to still another embodiment.

Referring to FIG. 24, the display device according to the present embodiment is different from the display device according to the embodiment of FIG. 23, in that the lower adhesive member GAM is further disposed not only on the first non-slimming portion NEP1, but also on other non-slimming portions NEP2 to NEP4 of the first substrate 100, the lower reinforcing member GRP is also further disposed not only on the first non-slimming portion NEP1, but also on other non-slimming portions NEP2 to NEP4 of the first substrate 100, the upper adhesive member GAM is further disposed not only on the fifth non-slimming portion NEP5, but also on other non-slimming portions NEP6 to NEP8 of the second substrate 200, and the upper reinforcing member GRP is also further disposed not only on the fifth non-slimming portion NEP5, but also on other non-slimming portions NEP6 to NEP8 of the second substrate 200.

Since other descriptions have been made with reference to FIG. 23, a detailed description thereof will be omitted.

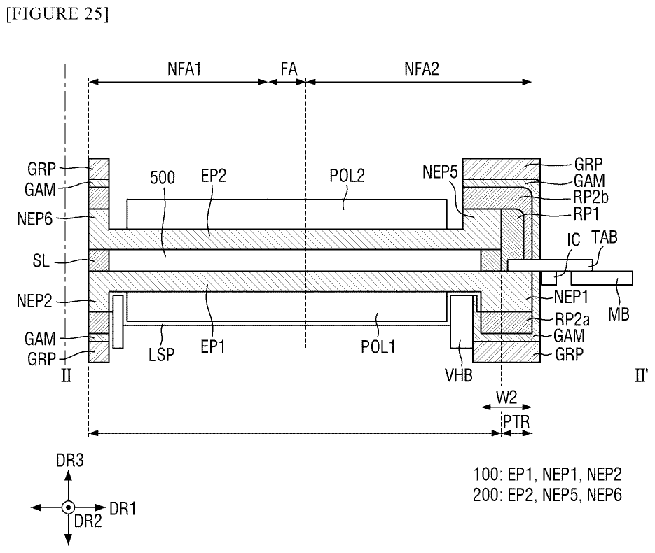

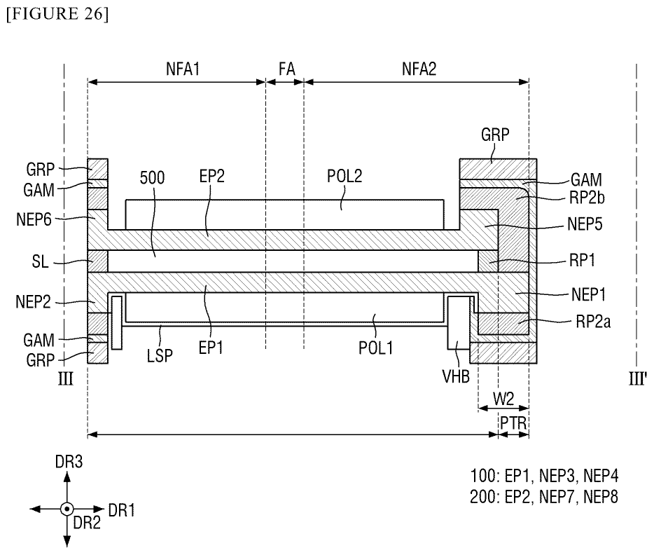

FIGS. 25 and 26 are cross-sectional views of a display device according to still another embodiment.

Referring to FIGS. 25 and 26, the present embodiment is different from the embodiment of FIG. 24 in that the upper adhesive member GAM according to FIG. 24 additionally extends on the side surface of the fifth non-slimming portion NEP5.

More specifically, as illustrated in FIG. 25, in an area where the driving connection film TAB is disposed, the upper adhesive member GAM may further extend to the side surface of the fifth non-slimming portion NEP5 so as to be in direct contact with the upper surface of the driving connection film TAB. However, the upper adhesive member GAM and the lower adhesive member GAM may be spaced apart from each other with the driving connection film TAB interposed therebetween.

However, as illustrated in FIG. 26, in an area where the driving connection film TAB is not disposed, the upper adhesive member GAM may be in direct contact with the lower adhesive member GAM. That is, the adhesive member GAM according to the present embodiment may be in contact with all of the outer side surface of the second upper resin RP2b, the outer side surface of the first non-slimming portion NEP1, and the outer side surface of the second lower resin RP2a that form one side surface of the display device 1.

According to the present embodiment, because the upper adhesive member GAM additionally extends on the side surface of the fifth non-slimming portion NEP5, when a physical impact is applied from the outside to the outer side surface of the fifth non-slimming portion NEP5 of the second substrate 200, the upper adhesive member GAM may cushion the physical impact, thereby preventing in advance the physical impact from being applied to the boundary between the inner side surface of the first non-slimming portion NEP1 of the first substrate 100 and the lower slimming portion EP1, which is a portion that is very vulnerable to external impact.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it should be understood that the embodiments described above are illustrative in all aspects and not restrictive.

1. A display device comprising:
a color filter substrate;
a transistor substrate including an overlapping portion facing the color filter substrate and overlapping the color filter substrate, and a protruding portion protruding further outward than the color filter substrate;
a driving connection film attached on the protruding portion of the transistor substrate; and
an adhesive member disposed on a lower side of the protruding portion of the transistor substrate,
wherein the transistor substrate includes a first slimming portion, and a first non-slimming portion that is disposed around the first slimming portion in plan view and has a thickness greater than the thickness of the first slimming portion,
the color filter substrate includes a second slimming portion, and a second non-slimming portion that is disposed around the second slimming portion in plan view and has a thickness greater than the thickness of the second slimming portion,
the first non-slimming portion includes a (1-1)-th non-slimming portion disposed across the protruding portion and the overlapping portion,
the second non-slimming portion includes a (2-1)-th non-slimming portion,
an inner side surface of the (1-1)-th non-slimming portion is positioned further outward than an inner side surface of the (2-1)-th non-slimming portion, and
the adhesive member overlaps the (1-1)-th non-slimming portion.

2. The display device of claim 1, further comprising a first resin in direct contact with the driving connection film and in direct contact with an outer side surface of the (2-1)-th non-slimming portion.

3. The display device of claim 2, further comprising a second resin including a second lower resin directly disposed on a lower surface of the (1-1)-th non-slimming portion, and a second upper resin directly disposed on an upper surface of the (2-1)-th non-slimming portion.

4. The display device of claim 3, wherein the second upper resin is in direct contact with an upper surface of the first resin and an outer side surface of the first resin.

5. The display device of claim 4, further comprising a lower reinforcing member disposed on a lower surface of the adhesive member.

6. The display device of claim 5, wherein the adhesive member is in direct contact with an inner side surface, a lower surface, and an outer side surface of the second lower resin, and the adhesive member is in direct contact with an outer side surface of the (1-1)-th non-slimming portion.

7. The display device of claim 6, wherein a strength of the lower reinforcing member is greater than a strength of the adhesive member.

8. The display device of claim 7, wherein the strength of the adhesive member is greater than a strength of the first resin and a strength of the second resin, respectively.

9. The display device of claim 8, wherein the lower reinforcing member is made of the same material as the transistor substrate.

10. The display device of claim 5, further comprising a first polarizing member disposed on a lower surface of the first slimming portion, and a second polarizing member disposed on an upper surface of the second slimming portion.

11. The display device of claim 10, further comprising a light blocking tape disposed on a lower side of the first polarizing member,
the light blocking tape is in direct contact with the first polarizing member, the lower surface of the first slimming portion exposed by the polarizing member, and the inner side surface of the (1-1)-th non-slimming portion.

12. The display device of claim 11, further comprising a double-sided tape disposed on a lower side of the lower surface of the first slimming portion exposed by the first polarizing member.

13. The display device of claim 12, wherein the adhesive member is in direct contact with an outer side surface of the double-sided tape.

14. The display device of claim 4, further comprising an upper reinforcing member overlapping the second upper resin,
wherein the upper reinforcing member includes the same material as the lower reinforcing member.

15. The display device of claim 14, wherein an inner side surface of the upper reinforcing member is positioned further inward than an inner side surface of the lower reinforcing member.

16. The display device of claim 1, wherein a driving chip is mounted on the driving connection film, and
in a state in which the driving connection film is unfolded, the lower reinforcing member does not overlap the driving chip at all in a thickness direction.

17. A method of fabricating a display device, the method comprising:
preparing an upper target substrate and a lower target substrate facing the upper target substrate, the lower target substrate including an overlapping portion overlapping the upper target substrate, a protruding portion protruding further outward than the upper target substrate, and a driving connection film connected to the protruding portion and having a driving chip mounted thereon;
disposing a first resin in direct contact with the driving connection film and in direct contact with an outer side surface of the upper target substrate;
disposing a second lower resin on an edge portion of the lower target substrate and disposing a second upper resin on an edge portion of the upper target substrate;
masking the edge portion of the lower target substrate, the edge portion of the upper target substrate, and the driving connection film using a masking member;
forming a lower substrate including a first slimming portion and a first non-slimming portion around the first slimming portion, and an upper substrate including a second slimming portion and a second non-slimming portion around the second slimming portion, respectively, by slimming the lower target substrate and an exposed portion of the upper target substrate;
removing the masking member from the lower substrate and the upper substrate;
disposing a polarizing member on each of the first slimming portion and the second slimming portion;
bending the lower substrate and the upper substrate; and
disposing an adhesive member on a lower side of the protruding portion of the lower substrate,
wherein the first non-slimming portion includes a (1-1)-th non-slimming portion disposed across the protruding portion and the overlapping portion,
the second non-slimming portion includes a (2-1)-th non-slimming portion,
an inner side surface of the (1-1)-th non-slimming portion is positioned further outward than an inner side surface of the (2-1)-th non-slimming portion, and
the adhesive member overlaps the (1-1)-th non-slimming portion.

18. The method of claim 17, wherein in the disposing of the second upper resin, the second upper resin is in direct contact with an outer side surface of the first resin.

19. The method of claim 18, further comprising a lower reinforcing member disposed on a lower surface of the adhesive member,
wherein the adhesive member is in contact with an inner side surface, a lower surface, and an outer side surface of the second lower resin.

20. The method of claim 19, wherein the adhesive member is in direct contact with an outer side surface of the (1-1)-th non-slimming portion,
a strength of the lower reinforcing member is greater than a strength of the adhesive member, and
the strength of the adhesive member is greater than a strength of the first resin and a strength of the second upper resin and the second lower resin, respectively.
